(19) United States
(12) Patent Application Publication
(10) Pub. No.: US 2026/0129805 A1
(43) Pub. Date: May 7, 2026

(54) COOLING SYSTEM

(71) Applicant: Tusas- Turk Havacilik Ve Uzay Sanayii Anonim Sirketi, Kahramankazan, Ankara (TR)

(72) Inventors: Durukan TAMKAN, Kahramankazan, Ankara (TR); Hamdi Alpay KUCUKER, Kahramankazan, Ankara (TR)

(73) Assignee: Tusas- Turk Havacilik Ve Uzay Sanayii Anonim Sirketi, Kahramankazan, Ankara (TR)

(21) Appl. No.: 19/116,405

(22) PCT Filed: Sep. 25, 2023
(86) PCT No.: PCT/TR2023/051020

§ 371 Date: Mar. 28, 2025

(30) Foreign Application Priority Data
Sep. 29, 2022 (TR) 2022/014919

(51) Int. Cl. H05K 7/20

(52) U.S. Cl. CPC H05K 7/20563

(57) ABSTRACT

The present invention relates to at least one body (2) in an air and/or space vehicle; at least one avionics equipment (3) positioned on the body (2); at least one inlet port (4) located on the body (2); a coolant (A) transmitted into the body through the inlet port (4); at least one transmission line (5) removably mounted on the inlet port (4), thus enabling the transmission of coolant (A) into the body (2) for cooling the avionics equipment (3); at least one void (6) forming the internal volume of the body (2); at least one hole (7) on the body (2), which allows the coolant (A) to be passed through the void (6) to the avionics equipment (3), thus allowing a temperature value of the avionics equipment (3) to be decreased.

This invention relates to a cooling system developed to reduce temperatures of equipment in air and/or space vehicles.

Most equipment requires active cooling. For this reason, both racks and cooling lines are used in an area to position the equipment. Cooling lines occupy space in the area and increase costs in production and assembly processes. As the cooling lines are closer to the equipment, cooling efficiency increases; however, since they use a predetermined space for the equipment and equipment carrier elements, it causes heavier carriers to be designed.

U.S. Pat. No. 9,526,190B2, which is included in the known-state of the art, discloses a system in which avionics rack modules enable the transportation of multiple electronic equipment arranged side by side. Cooling air is moved through avionics equipment to cool equipment elements. Each piece of avionics equipment is also mounted to the rack module via a support chair as described above. According to said document, the rack modules are mounted on the channels. Additionally, there are holes on the structure in the form of a seat to provide cooling. Therefore, air passage is provided between the air flow channel and the equipment. JP3644176B2, which is included in the known-state of the art, discloses a panel with an increased strength, which is used for assembly purposes in air and/or space vehicles and also allows pipes to be passed in order to carry out heat transfer.

Thanks to a cooling system according to the present invention, a lighter cooling system with more effective cooling is provided.

Another object of the invention is to provide the strength required for more effective cooling and transportation of avionics equipment by using the structural properties of the plate itself. A further object of the invention is to increase the static strength in transporting avionics equipment, thanks to the structural features of the plate in the cooling system.

The cooling system realized to achieve the object of the invention, which is defined in the first claim and other claims dependent thereon, comprises at least one body positioned in an air and/or space vehicle; at least one avionics equipment positioned on the body; at least one inlet port located in the body to provide access to the internal volume of the body; at least one transmission line removably mounted on the inlet port and placed almost completely at the inlet port for transmitting a coolant, i.e. cooling air, to the internal volume of the body for the purpose of cooling the avionics equipment positioned on the body; at least one void that forms the internal volume of the body so as to fill the internal volume of the body; at least one hole positioned on the body, which allows the coolant transmitted to the void by the transmission line to pass through the void and contact the avionics equipment in order to transmit the coolant to the avionics equipment on the body and to cool the heated avionics equipment by reducing a temperature to a value predetermined by the user.

The cooling system according to the invention comprises a plurality of protrusions produced in a user-predetermined geometric form in the void, next to the inlet port, from the inner surface of the body opposite the inlet port, wherein the protrusions extend towards the inner surfaces of the body and the inlet opening to fill the void, thus allowing the coolant transmitted through the inlet port to the void to be directed in the void in a direction predetermined by the user; at least one channel formed in the void, between at least two protrusions; the protrusion enabling the coolant transmitted from the inlet port to the void to be transmitted to the channels located in line with the holes without being distributed randomly within the void, thus allowing the coolant filled into the channels to be transmitted to the avionics equipment through the holes and allowing the avionics equipment to be cooled more effectively.

In an embodiment of the invention, the cooling system comprises the protrusion in a geometry predetermined by the user, which extends from the inner surface of the body towards the inlet port so as to be opposite thereto, wherein said inner surface of the body is opposite to the inlet port and in contact with the void.

In an embodiment of the invention, the cooling system comprises a plurality of carrier plates positioned opposite each other on the body, with at least one avionics equipment therebetween, wherein the avionics equipment is mounted removably on the carrier plates, thus allowing the avionics equipment to be carried on the body.

In an embodiment of the invention, the cooling system comprises a plurality of avionics equipment each located in the body, which are positioned on two carrier plates to extend in line with the protrusion.

In an embodiment of the invention, the cooling system comprises at least one groove located on the carrier plate placed on the body, so as to be opposite and in contact with the inlet port on the body;

In an embodiment of the invention, the cooling system comprises at least one transmission conduit removably positioned in the groove and inlet port, with one end connected to the transmission line and the other end reaching into the void, thus allowing the coolant transmitted through the transmission line to be passed through the groove and inlet port towards the void without any loss.

In an embodiment of the invention, the cooling system comprises at least one upper cover panel located integrally with the body on the surface of the body facing the avionics equipment; a plurality of holes which are located in line with each channel on the upper cover panel in order to transmit the coolant to the gaps between at least two avionics equipment, wherein the holes are located one after the other on the upper cover panel, each at a user-predetermined distance from each other, in line with the channels.

In an embodiment of the invention, the cooling system comprises the upper cover panel positioned on the body to enable the high temperature heat generated on the avionics equipment to be removed from the avionics equipment by conduction through the carrier plates on which the avionics equipment is mounted, wherein a space is provided between the upper cover panel and the avionics equipment in a volume predetermined by the user.

In an embodiment of the invention, the cooling system comprises a plurality of fins extending on lateral surfaces of the avionics equipment in line with the holes, so as to almost completely cover the lateral surfaces of the avionics equipment and to be sequential on the lateral surfaces, wherein the fins allow the coolant transmitted through the holes to be carried and moved over the avionics equipment.

In an embodiment of the invention, the cooling system comprises a lower surface that does not face the avionics equipment of the body and is located mirror symmetrically to the upper cover panel with respect to the body; at least one lower cover panel located integrally on the body, almost completely covering the lower surface.

In an embodiment of the invention, the cooling system comprises the body between the carrier plates, with at least two opposite sides thereof mounted on the carrier plate.

In an embodiment of the invention, the cooling system comprises the body produced in a honeycomb geometry, i.e. honeycomb core, between the lower cover panel and the upper cover panel, integrally with the lower cover panel and the upper cover panel.

In an embodiment of the invention, the cooling system comprises the body produced by an additive manufacturing method in a geometry predetermined by the user.

In an embodiment of the invention, the cooling system comprises carrier plates made of a metal material predetermined by the user.

In an embodiment of the invention, the cooling system comprises avionics equipment used to manage flight systems on air and/or space vehicles.

In an embodiment of the invention, the cooling system comprises the transmission line which is supplied with the coolant, i.e. the cold air transmitted by the air conditioning systems (ECS) in air and/or space vehicles, and allows the coolant (A) to be transmitted to the void in the body.

The cooling system realized to achieve the object of the present invention is illustrated in the attached drawings, in which:

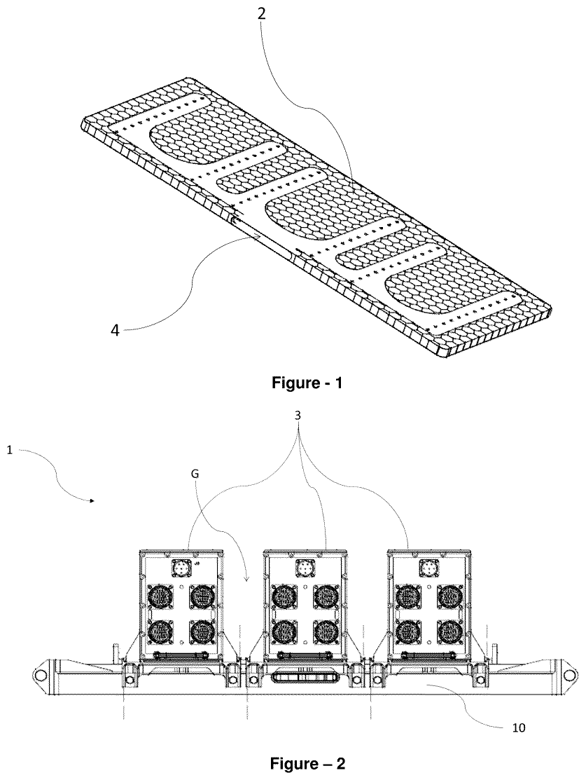

FIG. 1 is a perspective view of the body.

FIG. 2 is a front view of the cooling system.

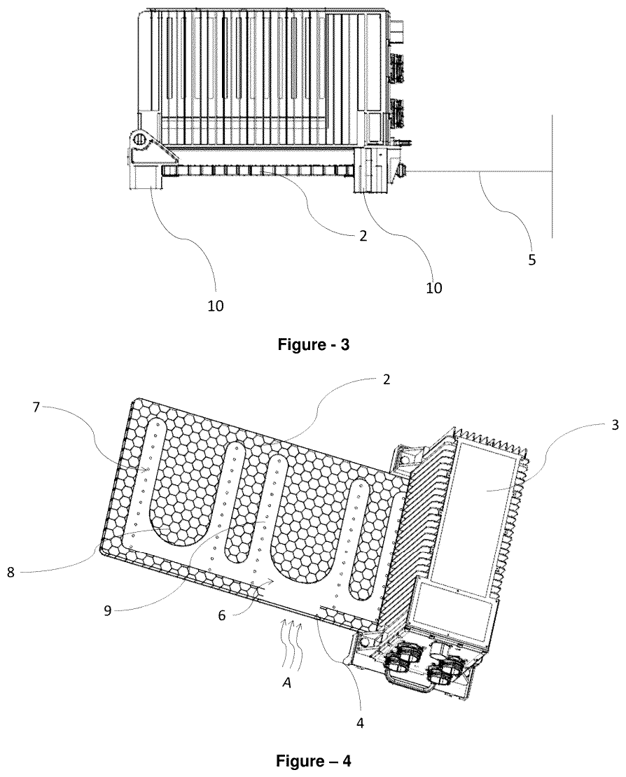

FIG. 3 is a side view of the body, transmission line and carrier plate.

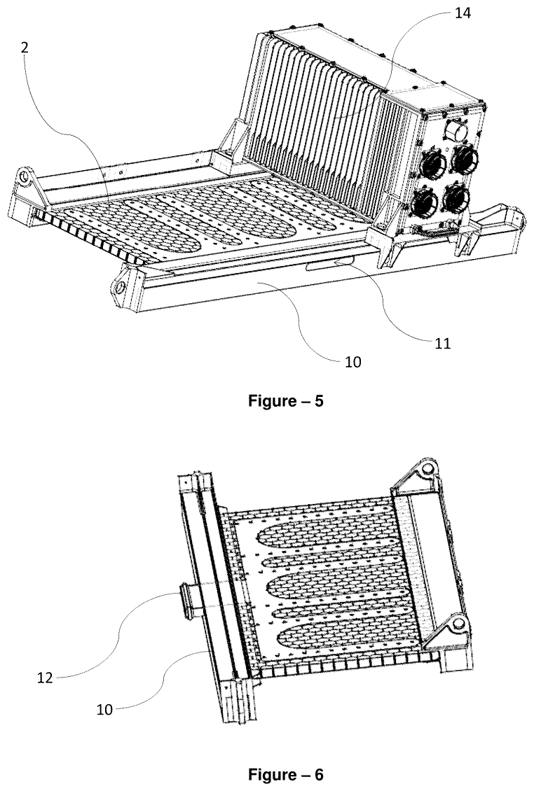

FIG. 4 is a perspective view of the body, inlet port, avionics equipment, hole, protrusion, channel and void.

FIG. 5 is a perspective view of the fin and groove.

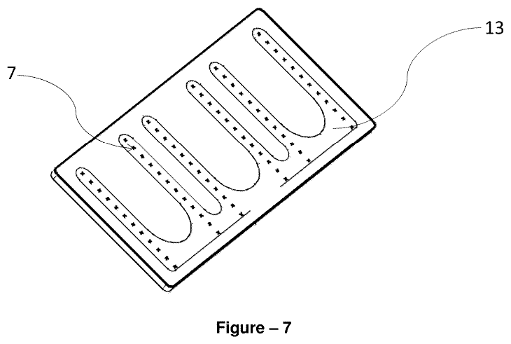

FIG. 6 is a perspective view of the carrier plate and transmission conduit.

FIG. 7 is a perspective view of the upper cover panel and the hole.

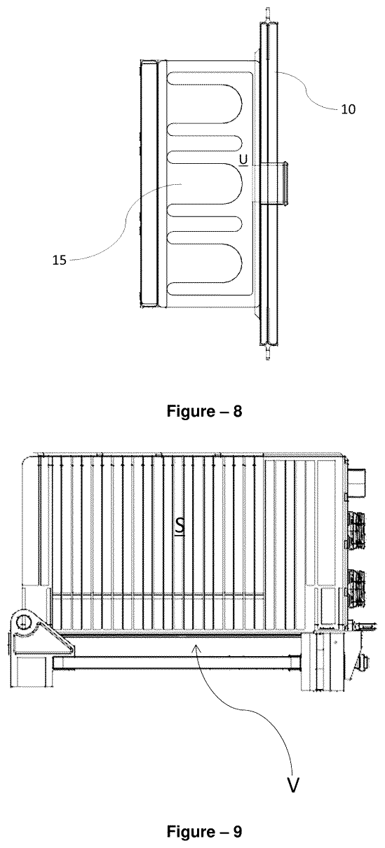

FIG. 8 is a bottom view of the lower cover panel and lower surface.

FIG. 9 is a side view of the avionics equipment and gap.

All the parts illustrated in figures are individually assigned a reference numeral and the corresponding terms of these numbers are listed below:
1. Cooling System
2. Body
3. Avionics Equipment
4. Inlet Port
5. Transmission line
6. Void
7. Hole
8. Protrusion
9. Channel
10. Carrier Plate
11. Groove
12. Transmission conduit
13. Upper Cover Panel
14. Fin
15. Lower Cover Panel
(A) Coolant
(G) Gap
(V) Space
(S) Lateral Surface
(U) Lower Surface

The cooling system (1) comprises at least one body (2) in an air and/or space vehicle; at least one avionics equipment (3) positioned on the body (2); at least one inlet port (4) located on the body (2); a coolant (A) transmitted into the body through the inlet port (4); at least one transmission line (5) removably mounted on the inlet port (4), thus enabling the transmission of coolant (A) into the body (2) for cooling the avionics equipment (3); at least one void (6) forming the internal volume of the body (2); at least one hole (7) on the body (2), which allows the coolant (A) to be passed through the void (6) to the avionics equipment (3), thus allowing a temperature value of the avionics equipment (3) to be decreased.

The cooling system (1) according to the invention comprises a plurality of protrusions (8) in the body (2), which extend in the void (6) in a geometric form predetermined by the user, thus enabling the coolant (A) that is transmitted through the inlet port (4) to the void (6) to be directed; at least one channel (9) located in the void (6) so as to remain between the protrusions (8) and extend in the same direction as the protrusions (8); the protrusion (8) that allows the coolant (A) transmitted to the void (6) to be directed to the channel (9) and transmitted to the avionics equipment (3) through the holes (7) that are located on the body (2) in line with the channel (9).

In order to cool the avionics equipment (3) in an air and/or space vehicle, the coolant (A), i.e. the cooling air, is transmitted into the body (2) containing the avionics equipment (3), by means of the transmission line (5) connected to the inlet port (4) on the body (2). There is at least one hole (7) on the body (2) in order to ensure that the coolant (A), which is transmitted to the void (6) forming the internal volume of the body (2), is transmitted to the avionics equipment (3) as a result of its movement in the void (6). Therefore, the coolant (A) transmitted into the void (6) through the inlet port (4) exits the void (6) through the holes (7), and reaches the avionics equipment (3).

In order to deliver the coolant (A), which is transmitted through the inlet port (4) into the void (6), towards the holes (7) in a short period of time and effectively, a plurality of protrusions (8) are provided in the void (6) that extend to fill the void (6) and allow the coolant (A) transmitted through the inlet port (4) to be directed as a result of hitting the surface thereof. There is at least one channel (9) on the body (2), which is formed in the void (6) as a result of at least two protrusions (8) extending with a distance therebetween in the void (6), the channel (9) being in the same direction as the protrusions (8). Thanks to the protrusions (8), the coolant (A) transmitted through the inlet port (4) to the void (6) is directed and transmitted to the channels (9) as a result of hitting the walls of the protrusion (8). In this way, the fluid can be transmitted more regularly to the channels (9) and the holes (7) located on the body (2) in line with the channels (9) (FIG. 1, FIG. 3, FIG. 4).

In an embodiment of the invention, the cooling system (1) comprises the protrusion (8) in a form predetermined by the user, which extends towards the inlet port (4) so as to be opposite the inlet port (4). The protrusions (8) extend in the void (6) from the inner surface of the void (6) opposite the inlet port (4), towards the inlet port (4), and towards the inner surfaces of the void (6) located on the sides of the inlet port (4). Thus, the coolant (A) can be directed more effectively to the channels (9) thanks to the predetermined geometric forms of the protrusions (8) positioned side by side in the void (6), facing the inlet port (4) (FIG. 4).

In an embodiment of the invention, the cooling system (1) comprises a plurality of carrier plates (10) positioned opposite each other on the body (2) with avionics equipment (3) therebetween, and allowing the avionics equipment (3) to be positioned and carried on the body (2). The avionics equipment (3) are mounted removably on the carrier plates (10) that are opposite each other, such that a user-predetermined distance is provided between the avionics equipment (3). Thus, the avionics equipment (3) is carried and fixed on the body (2) (FIG. 2).

In an embodiment of the invention, the cooling system (1) comprises a plurality of avionics equipment (3) located on the carrier plate (10), in line with the protrusion (8), each at a distance predetermined by the user from the other. Avionics equipment (3) is mounted on the carrier plate (10) to be in line with the protrusions (8) inside the body (2) and to extend almost parallel thereto. Thus, the avionics equipment (3) is positioned in different alignments with the channels (9) located between the protrusions (8) (FIG. 5).

In an embodiment of the invention, the cooling system (1) comprises at least one groove (11) which is located on the carrier plate (10), opposite the inlet port (4), and through which the coolant (A) is transmitted; at least one transmission conduit (12) removably inserted inside the groove (11) and inlet port (4), thus allowing the fluid transmitted by the transmission line (5) to be transmitted into the body (2) without loss. There is at least one groove (11) on the carrier plates (10) located on the body (2), in order to maintain the transmission of coolant (A) to the void (6). The carrier plate (10) is positioned on the body (2) so that the groove (11) and the inlet port (4) are opposite each other. One end of the transmission conduit (12) that is positioned in the inlet port (4) and groove (11) is connected to the transmission line (5), and the other end thereof is located to transmit the coolant (A) to the void (6). In this way, the coolant (A) conveyed to the void (6) via the groove (11) and inlet port (4) is transmitted almost without loss (FIG. 5, FIG. 6).

In an embodiment of the invention, the cooling system (1) comprises at least one upper cover panel (13) located on the body (2), integral with the body (2); at least one gap (G) between two avionics equipment (3); a plurality of holes (7) located consecutively on the upper cover panel (13) in line with the channels (9), each at a predetermined distance from the other, thereby allowing the coolant (A) to be transmitted to the gap (G). Holes (7) are provided in line with the channels (9), on the upper covering panel (13) that is integral with the body (2). Therefore, the coolant (A) transmitted into the void (6) and directed inside the channels (9) via the protrusions (8) passes through the holes (7) on the upper cover panel (13), after which it is transmitted to the gap (G) at the distance predetermined by the user between the avionics equipment (3), each of which is aligned with the protrusion (8), so that temperatures of the avionics equipment (3) is decreased (FIG. 2, FIG. 7).

In an embodiment of the invention, the cooling system (1) comprises a space (V) located between the avionics equipment (3) and the upper cover panel (13) at a distance predetermined by the user; the upper cover panel (13) which allows the heat generated on the avionics equipment (3) to be removed from the avionics equipment (3) by conduction only through the carrier plates (10), due to the space (V). Avionics equipment (3) is mounted on the carrier plates (10) with a predetermined amount of space (V) between the avionics equipment (3) and the upper cover panel (13). Thus, since the avionics equipment (3) only contact the carrier plates (10), the heat generated on the avionics equipment (3) with high temperatures is removed from the avionics equipment (3) by conduction, only through the carrier plates (10) (FIG. 9).

In an embodiment of the invention, the cooling system (1) comprises a plurality of lateral surfaces(S) on the avionics equipment (3); a plurality of fins (14) located on the lateral surfaces(S) so as to almost completely surround the lateral surfaces(S) and to be in line with the holes (7), thereby enabling the coolant (A), which is transmitted to the avionics equipment (3) through the holes (7), to be moved longitudinally along the lateral surfaces (S). Thanks to the fins (14) extending along the vertical length of the avionics equipment (3) on the lateral surfaces(S) of the avionics equipment (3), in line with the holes (7) and almost completely surrounding the lateral surfaces(S), the coolant (A) transmitted to the gap (G) through the holes (7) is moved along the surface of the avionics equipment (3), so that the temperature of the avionics equipment (3) is decreased effectively (FIG. 5).

In an embodiment of the invention, the cooling system (1) comprises a lower surface (U) located at a lower part of the body (2); at least one lower cover panel (15) located on the lower surface (U) of the body (2) so as to almost completely surround the lower surface (U) and to be integral with the body (2). At least one lower cover panel (15) is provided on the body (2), integral with the body (2) and mirror symmetrical to the upper cover panel (13) with respect to the body (2), on a surface of the body (2) not facing the avionics equipment (3). Thus, the coolant (A) transmitted through the inlet port (4) to the void (6) exits the body (2) only through the holes (7) (FIG. 8).

In an embodiment of the invention, the cooling system (1) comprises the body (2) which is mounted removably on the carrier plates (10), with the edges thereof remaining at least partially in the carrier plates (10). Thanks to the body (2) mounted on at least two opposing carrier plates (10) at the ends thereof, the integrity of the carrier plates (10), which allow the avionics equipment (3) to be carried thereon, is ensured.

In an embodiment of the invention, the cooling system (1) comprises the body (2), which is a honeycomb core and located between the lower cover panel (15) and the upper cover panel (13). The protrusions (8) in the body (2), and the body (2) forming the walls surrounding the protrusions (8) are provided in a honeycomb geometry and with a honeycomb core structure between the lower cover panel (15) and the upper cover panel (13). Therefore, the body (2) in the cooling system (1) is ensured to be lighter and of higher strength.

In an embodiment of the invention, the cooling system (1) comprises the body (2) produced by an additive manufacturing method, in a geometry predetermined by the user. The protrusion (8) in honeycomb geometry and the body (2), which almost completely surrounds the protrusions (8) and contains the protrusions (8), are produced with less margin of error and in a shorter time by using the additive manufacturing method.

In an embodiment of the invention, the cooling system (1) comprises the carrier plate (10) made of a metal material. Therefore, the heat of high-temperature avionics equipment (3) can be removed from the avionics equipment (3) by conduction.

In an embodiment of the invention, the cooling system (1) comprises the avionics equipment (3) provided on an air and/or space vehicle. The temperatures of the avionics equipment (3), which contains the systems necessary to control the air and/or space vehicle, are kept within a range predetermined by the user by means of the cooling system (1).

In an embodiment of the invention, the cooling system (1) comprises the transmission line (5) that allows the coolant (A) transmitted by an air conditioning system of the air and/or space vehicle to be transmitted into the body (2). The coolant (A) transmitted from the air conditioning system into the void (6) is carried through the transmission line (5).

1. A cooling system (1) comprising at least one body (2) in an air and/or space vehicle; at least one avionics equipment (3) positioned on the body (2); at least one inlet port (4) located on the body (2); a coolant (A) transmitted into the body through the inlet port (4); at least one transmission line (5) removably mounted on the inlet port (4), thus enabling the transmission of coolant (A) into the body (2) for cooling the avionics equipment (3); at least one void (6) forming the internal volume of the body (2); at least one hole (7) on the body (2), which allows the coolant (A) to be passed through the void (6) and transmitted to the avionics equipment (3), thus allowing a temperature value of the avionics equipment (3) to be decreased, characterized by a plurality of protrusions (8) in the body (2), which extend in the void (6) in a geometric form predetermined by the user, thus enabling the coolant (A) that is transmitted through the inlet port (4) to the void (6) to be directed; at least one channel (9) located in the void (6) so as to remain between the protrusions (8) and extend in the same direction as the protrusions (8); at least one protrusion (8) that allows the coolant (A) transmitted to the void (6) to be directed to the channel (9) and transmitted to the avionics equipment (3) through the holes (7) that are located on the body (2) in line with the channel (9).

2. A cooling system (1) according to claim 1, wherein the protrusion (8) in a form predetermined by the user, which extends towards the inlet port (4) so as to be opposite the inlet port (4).

3. A cooling system (1) according to claim 4, wherein a plurality of carrier plates (10) positioned opposite each other on the body (2) with avionics equipment (3) therebetween, and allowing the avionics equipment (3) to be positioned and carried on the body (2).

4. A cooling system (1) according to claim 3, wherein a plurality of avionics equipment (3) located on the carrier plate (10), in line with the protrusion (8), each at a distance predetermined by the user from the other.

5. A cooling system (1) according to claim 3, wherein at least one groove (11) which is located on the carrier plate (10), opposite the inlet port (4), and through which the coolant (A) is transmitted; at least one transmission conduit (12) removably inserted inside the groove (11) and inlet port (4), thus allowing the fluid transmitted by the transmission line (5) to be transmitted into the body (2) without loss.

6. A cooling system (1) according to claim 1, wherein at least one upper cover panel (13) located on the body (2), integral with the body (2); at least one gap (G) between two avionics equipment (3); a plurality of holes (7) located consecutively on the upper cover panel (13) in line with the channels (9), each at a predetermined distance from the other, thereby allowing the coolant (A) to be transmitted to the gap (G).

7. A cooling system (1) according to claim 6, wherein a space (V) located between the avionics equipment (3) and the upper cover panel (13) at a distance predetermined by the user; the upper cover panel (13) which allows the heat generated on the avionics equipment (3) to be removed from the avionics equipment (3) by conduction only through the carrier plates (10), thanks to the space (V).

8. A cooling system (1) according to claim 1, wherein a plurality of lateral surfaces(S) on the avionics equipment (3); a plurality of fins (14) located on the lateral surfaces (S) so as to almost completely surround the lateral surfaces(S) and to be in line with the holes (7), thereby enabling the coolant (A), which is transmitted to the avionics equipment (3) through the holes (7), to be moved longitudinally along the lateral surfaces(S).

9. A cooling system (1) according to claim 1, wherein a lower surface (U) located at a lower part of the body (2); at least one lower cover panel (15) located on the lower surface (U) of the body (2) so as to almost completely surround the lower surface (U) and to be integral with the body (2).

10. A cooling system (1) according to claim 3, wherein the body (2) which is mounted removably on the carrier plates (10), with the edges thereof remaining at least partially in the carrier plates (10).

11. A cooling system (1) according to claim 9, wherein the body (2), which is a honeycomb core and located between the lower cover panel (15) and the upper cover panel (13).

12. A cooling system (1) according to claim 1, wherein the body (2) produced by an additive manufacturing method, in a geometry predetermined by the user.

13. A cooling system (1) according to claim 3, wherein the carrier plate (10) made of a metal material.

14. A cooling system (1) according to claim 1, wherein the avionics equipment (3) provided on an air and/or space vehicle.

15. A cooling system (1) according to claim 1, wherein the transmission line (5) that allows the coolant (A) transmitted by an air conditioning system of the air and/or space vehicle to be transmitted into the body (2).
